(19) United States
(12) Patent Application Publication
(10) Pub. No.: US 2012/0135222 A1
(43) Pub. Date: May 31, 2012

(54) ALUMINUM ARTICLE AND METHOD FOR MANUFACTURING SAME

(75) Inventors: HSIN-PEI CHANG, Tu-Cheng (TW); WEN-RONG CHEN, Tu-Cheng (TW); HUANN-WU CHIANG, Tu-Cheng (TW); CHENG-SHI CHEN, Tu-Cheng (TW); HUA-YANG XU, Shenzhen (CN)

(73) Assignees: HON HAI PRECISION INDUSTRY CO., LTD., Tu-Cheng (TW); HONG FU JIN PRECISION INDUSTRY (ShenZhen) CO., LTD., Shenzhen City (CN)

(21) Appl. No.: 13/165,345

(22) Filed: Jun. 21, 2011

(30) Foreign Application Priority Data
Nov. 26, 2010 (CN) 201010561553.6

(51) Int. Cl. B32B 3/26; C23F 1/20; C23C 14/34

(52) U.S. Cl. 428/306.6; 204/192.1; 216/83

(57) ABSTRACT

An aluminum article includes a substrate comprising a surface having a plurality of nano-pores defined therein by chemical etching; and a transparent vacuum deposition layer deposited on the surface and filling the nano-pores.

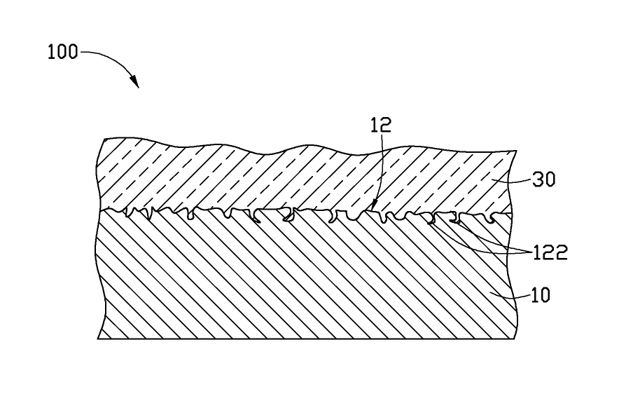

### CROSS-REFERENCE TO RELATED APPLICATIONS

The present application is related to co-pending U.S. Patent Applications (Attorney Docket No. US35004, US35007), each entitled “ALUMINUM ARTICLE AND METHOD FOR MANUFACTURING SAME”, by Zhang et al. These applications have the same assignee as the present application and have been concurrently filed herewith. The above-identified applications are incorporated herein by reference.

### BACKGROUND

1. Technical Field

The exemplary disclosure generally relates to aluminum articles and methods for manufacturing the aluminum articles.

2. Description of Related Art

Aluminum is remarkable for the metal's low density and good machining property. Articles made from aluminum and aluminum alloys are vital in the aerospace industry in addition to other areas of transportation, building and electronic device housings. To improve the appearance of aluminum or aluminum alloy articles, vacuum deposition is used to form a thin film or coating on aluminum or aluminum alloy articles. However, a typical vacuum deposition can only deposit mono-color coatings.

Therefore, there is room for improvement within the art.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the exemplary embodiment of a aluminum article and method for manufacturing the aluminum article. Moreover, in the drawings like reference numerals designate corresponding parts throughout the several views. Wherever possible, the same reference numbers are used throughout the drawings to refer to the same or like elements of an embodiment.

The FIGURE illustrates a cross-sectional view of an embodiment of an aluminum article.

### DETAILED DESCRIPTION

Referring to the FIGURE, an exemplary embodiment of an aluminum article 100 includes a substrate 10 and a transparent vacuum deposition layer 30 deposited on the substrate 10. The aluminum article 100 may be a housing of an electronic device. The substrate 10 is made of aluminum or aluminum alloy. The substrate 10 includes a surface 12 having a plurality of nano-pores 122 defined therein. Each nano-pore 122 may have a different pore opening size from that of at least one of other nano-pores 122, and each nano-pore 122 has a pore opening size between 30 nanometers (nm) and 250 nm, preferably is between 30 nm and 150 nm. Each nano-pore 122 may have a depth different from that of at least one of other nano-pores 122, and each nano-pore 122 has a depth between 20 nm and 300 nm, preferably is between 20 nm and 100 nm. The nano-pores 122 may be formed by chemical etching.

The vacuum deposition layer 30 is deposited on the surface 12, and the nano-pores are wholly/partly filled by the vacuum deposition layer 30. The vacuum deposition layer 30 may be deposited by metal, metal-oxide or non-metal oxide. The metal may be titanium, chromium, aluminum, zinc or zirconium. The metal-oxide may be titanium-oxide, chromium-oxide, aluminum-oxide or zirconium-oxide. The non-metal oxide may be silicone oxide. When the vacuum deposition layer 30 is deposited by metal, the thickness of the vacuum deposition layer 30 is between 50 nm and 150 nm because when the thickness of the vacuum deposition layer 30 is more than 150 nm, the vacuum deposition layer 30 become non-transparent, but when the thickness of the vacuum deposition layer 30 is smaller than 150 nm, the vacuum deposition layer 30 is transparent. When the vacuum deposition layer 30 is made of metal-oxide or non-metal oxide, the thickness of vacuum deposition layer 30 is between the 50 nm and 2 micrometers.

Due to the fact that each nano-pore 122 has a depth different from that of at least one of other nano-pores 122, the thickness of one place of the vacuum deposition layer 30 corresponding to one of nano-pores 122 may be different from the thickness of other places of the vacuum deposition layer 30 corresponding to other nano-pores 122. For example, parts of the vacuum deposition layer 30 deposited on the surface 12 is thinner than the reminder of the vacuum deposition layer 30 deposited in the nano-pores 122, and this also can be seen in the figure. Because optical path differences is different according to different thicknesses of the vacuum deposition layer 30, different colors would be appeared at different thicknesses of the vacuum deposition layer 30 when the vacuum deposition layer 30 is illuminated by light. Thus, the aluminum article 100 can appear multi-colored when seen from the surface 12.

A method for manufacturing the aluminum article 100 manufactured by vacuum deposition may include at least the following steps.

A substrate 10 including a surface 12 is provided. The substrate 10 may be made of aluminum or aluminum alloy.

The substrate 10 is pretreated. For example, the substrate 10 may be washed with a solution (e.g., alcohol) for about 5 minutes, and then is washed with an acetone in an ultrasonic cleaner for about 30 minutes, to remove, e.g., grease, dirt, and/or impurities. The substrate 10 is washed by water, followed by drying. The substrate 10 may also be cleaned using chemical polishing with a solution including phosphorous acid of 85 wt %, nitric acid and water, at a temperature between 70 degree Celsius (° C.) and 80° C., for about 5 minutes. At this exemplary embodiment, the volume ratio of the phosphorous acid, the nitric acid and the water is 8:1:1.

The substrate 10 is treated by chemical etching, to form a plurality of nano-pores 122 on the surface 12. In this exemplary embodiment, the substrate 10 is etched by a solution containing FeCl₃ of 20 g/L.˜50 g/and hydrochloric acid of 4.2 mol/L˜5.4 mol/L, at a temperature of 20° C.˜40° C., for a time of 3˜15 seconds. During the substrate 10 is etched, the solution may be stirred by a magnetic stirrer.

The substrate 10 is treated by vacuum deposition, to from a vacuum deposition layer 30 on the substrate 10. The vacuum deposition may be vacuum sputtering deposition or vacuum evaporation, and the thickness of the vacuum deposition layer 30 can be controlled in above range by controlling a time of the vacuum deposition, to ensure the vacuum deposition layer 30 is transparent.

It is to be understood, however, that even through numerous characteristics and advantages of the exemplary disclosure have been set forth in the foregoing description, together with details of the system and function of the disclosure, the disclosure is illustrative only, and changes may be made in detail, especially in matters of shape, size, and arrangement of parts within the principles of the disclosure to the full extent indicated by the broad general meaning of the terms in which the appended claims are expressed.

What is claimed is:

1. An aluminum article, comprising:
a substrate comprising a surface having a plurality of nano-pores defined therein by chemical etching; and
a transparent vacuum deposition layer deposited on the surface and at least partially filling the nano-pores.

2. The aluminum article as claimed in claim 1, wherein the substrate is made of aluminum or aluminum alloy.

3. The aluminum article as claimed in claim 1, wherein each nano-pore has a different pore opening size from that of at least one of other nano-pores.

4. The aluminum article as claimed in claim 1, wherein each nano-pore has a pore opening size between 30 nm and 250 nm.

5. The aluminum article as claimed in claim 1, wherein each nano-pore has a pore opening size between 30 nm and 150 nm.

6. The aluminum article as claimed in claim 1, wherein each nano-pore has a depth different from that of at least one of other nano-pores.

7. The aluminum article as claimed in claim 1, wherein each nano-pore has a depth between 20 nm and 300 nm.

8. The aluminum article as claimed in claim 1, wherein each nano-pore has a depth between 20 nm and 100 nm.

9. The aluminum article as claimed in claim 1, wherein the vacuum deposition layer is deposited by metal, metal-oxide or non-metal oxide.

10. The aluminum article as claimed in claim 9, wherein the metal is titanium, chromium, aluminum or zirconium.

11. The aluminum article as claimed in claim 9, wherein the metal-oxide is titanium-oxide, chromium-oxide, aluminum-oxide or zirconium-oxide.

12. The aluminum article as claimed in claim 9, wherein the non-metal oxide is silicone oxide.

13. The aluminum article as claimed in claim 9, wherein when the vacuum deposition layer is deposited by metal, the thickness of the vacuum deposition layer is between 50 nm and 150 nm.

14. The aluminum article as claimed in claim 9, wherein when the vacuum deposition layer is made of metal-oxide or non-metal oxide, the thickness of vacuum deposition layer is between the 50 nm and 2 micrometers.

15. A method for manufacturing an aluminum article comprising steps of:
providing a substrate comprising a surface;
defining a plurality of nano-pores in the surface by chemical etching; and
depositing a transparent vacuum deposition layer on the surface, the transparent vacuum deposition layer at least partially filling the nano-pores.

16. The method of claim 15, wherein the substrate is made of aluminum or aluminum alloy.

17. The method of claim 15, wherein during the substrate is treated by chemical etching, the substrate is etched by a solution containing FeCl₃ of 20 g/L˜50 g/and hydrochloric acid of 4.2 mol/L˜5.4 mol/L, at a temperature of 20° C˜40° C., for a time of 3-15 seconds.

18. The method of claim 17, wherein during the substrate is treated by chemical etching, the solution is stirred by a magnetic stirrer.

19. The method of claim 15, wherein the substrate is treated by vacuum deposition, to from the vacuum deposition layer.

20. The method of claim 19, wherein the vacuum deposition is vacuum sputtering deposition or vacuum evaporation.
